(19) United States
(12) Patent Application Publication
(10) Pub. No.: US 2014/0319240 A1
(43) Pub. Date: Oct. 30, 2014

(54) Piezoelectric Actuator

(71) Applicant: Alexander Kuschel, Regensburg (DE)

(72) Inventor: Alexander Kuschel, Regensburg (DE)

(21) Appl. No.: 14/350,241

(22) PCT Filed: Oct. 5, 2012
(86) PCT No.: PCT/EP2012/069719

§ 371 Date: Apr. 7, 2014

(30) Foreign Application Priority Data
Oct. 6, 2011 (DE) 10 2011 084 107.5

(51) Int. Cl. F02M 51/06; H01L 41/053

(52) U.S. Cl. CPC F02M 51/0603; H01L 41/0533
USPC 239/102.2; 310/344

(57) ABSTRACT

A piezoelectric actuator for a fuel injector may include a piezoelement that can be deflected along the longitudinal axis in the longitudinal direction of the fuel injector, and a separating wall for protecting the piezoelement from an overflow of a medium from the fuel-guiding part of the fuel injector, the piezoelement being preconstrained in the axial direction by the separating wall.

### CROSS-REFERENCE TO RELATED APPLICATIONS

This application is a U.S. National Stage Application of International Application No. PCT/EP2012/069719 filed Oct. 5, 2012, which designates the United States of America, and claims priority to DE Application No. 10 2011 084 107.5 filed Oct. 6, 2011, the contents of which are hereby incorporated by reference in their entirety.

### TECHNICAL FIELD

The invention relates to a piezoelectric actuator for a fuel injector.

### BACKGROUND

Fuel injectors are known which are activated by means of a piezoelectric actuator. The piezoelectric actuator has a piezoelement which is accommodated in a housing. A cylindrical spring element surrounds the piezoelement in the longitudinal direction and compresses it, as a result of which prestress is generated in the piezoelement in order to maintain the dimensional stability of the piezoelement which usually comprises a large number of piezoceramic layers to each of which stress can be alternately provided.

DE 199 40 055 C1 presents a metering value with a piezoelement in which axial prestress is applied to the piezoelement by means of a coaxial metal bellows which surrounds the piezoelement.

DE 102 60 289 A1 presents an injector with a similar design, wherein the prestress is brought about here by means of a coaxial spring tube.

DE 10 2004 006 266 A1 presents an internal combustion engine injection device which is also similar and in which coaxial bellows bring about the prestress.

DE 199 06 467 A1 presents an injector with a piezoactuator in which axial prestress is brought about by means of a spring plate through which the actuator body runs in the axial direction.

DE 198 49 203 A1 presents a fuel injection valve having an axially acting spring which bears against an axial end of a piezoactuator.

### SUMMARY

One embodiment provides piezoelectric actuator for a fuel injector, comprising a piezoelement for performing axial activation, and a dividing wall for protecting the piezoelement from an overflow of a medium from the fuel injector, wherein the piezoelement is prestressed in the axial direction, and the prestress is brought about by the dividing wall, and wherein the dividing wall bears against an axial end of the piezoelement and extends transversely with respect to the direction of activation of the piezoelement.

In a further embodiment, the piezoelement is arranged in a housing between the dividing wall and a terminating element.

In a further embodiment, the terminating element comprises electrical terminals for actuating the piezoelement.

In a further embodiment, the dividing wall is shaped in a radially symmetrical fashion.

In a further embodiment, the dividing wall has a bead.

In a further embodiment, the dividing wall is curved in the direction of the piezoelement.

In a further embodiment, the dividing wall is composed of sheet steel.

### BRIEF DESCRIPTION OF THE DRAWINGS

Example embodiments are explained in detail below with reference to the figures, in which:

FIG. 1 shows a longitudinal section through a piezoelectric actuator;

FIG. 2 shows longitudinal sections through various exemplary dividing walls of the piezoelectric actuator according to FIG. 1; and

FIG. 3 shows a flowchart of a method for manufacturing the piezoelectric actuator from FIG. 1.

### DETAILED DESCRIPTION

Embodiments of the present invention provide a simplified piezoelectric actuator for a fuel injector.

According to some embodiments, a piezoelectric actuator for a fuel injector comprises a piezoelement which can be deflected in its longitudinal direction which usually points in the longitudinal direction of the fuel injector. A dividing wall protects the piezoelement from an overflow of a medium from fuel-guiding sections of the fuel injector. A mechanical prestress of the piezoelement in the axial direction is brought about by the dividing wall in cooperation with the housing of the dividing wall. In this context, the dividing wall bears against an axial end of the piezoelement and extends transversely with respect to the direction of activation of the piezoelement. As a result, an additional elastic element for compressing the piezoelement and possibly further elements for supporting this elastic element can be dispensed with, as a result of which manufacturing costs of the piezoelectric actuator can be lowered. The installation space which becomes free as a result of the elimination of the elastic element can be used to make the piezoelectric actuator more compact. Alternatively, the installation space which becomes free can be filled by a piezoelement which is increased in size, in order to implement a piezoelectric actuator with an increased power density and a comparatively small installation space.

The piezoelement is usually arranged in its housing between the dividing wall and a terminating element. The result is a piezoelectric actuator as a unit which can be handled separately, which can provide advantages during the mounting of the piezoelectric actuator for a fuel injector. Furthermore, the piezoelectric actuator can in this way be sealed hermetically so that the piezoelement is protected on all sides against penetration of a medium, for example fuel, which could damage the piezoelement.

The dividing wall can be shaped in a radially symmetrical fashion, that is to say symmetrically with respect to a longitudinal axis of the piezoelement. As a result, stresses within the dividing wall can act symmetrically, as a result of which the dividing wall can as far as possible withstand the prestress of the piezoelement even after a relatively large number of activations during which the dividing wall is shaped in each case, and is not deformed, for example asymmetrical stress in the course of time. In this context, the dividing wall can have a bead which may be embodied in a radially symmetrical fashion about the axis of symmetry of the dividing wall. The bead can be shaped in such a way that during a deflection process of the piezoelement a predetermined profile of the prestressing force is applied to the piezoelement. In one further embodiment, a plurality of radially symmetrical, i.e. concentric, beads can also be used.

The dividing wall can be curved in the direction of the piezoelement. As a result, a prestressing force, which can be applied to the piezoelement by means of the dividing wall can be increased. In addition, it is possible to adapt the profile of the prestressing force by means of the axial activation of the piezoelement by means of correspondingly shaped curvature. The dividing wall can be composed of sheet steel, as a result of which good manufacturability and processability is combined with high elasticity, high mechanical load bearing capacity and a high level of resistance against aggressive media such as, for example, fuel.

A method for manufacturing a piezoelectric actuator for a fuel injector comprises steps of making available a piezoelement for axial deflection in the longitudinal direction thereof, usually in the longitudinal direction of the fuel injector, of making available a dividing wall for protecting the piezoelement from an overflow of a medium from the fuel-guiding part of the fuel injector and of attaching the dividing wall to the piezoelement in such a way that prestressing of the piezoelement in the longitudinal direction of the piezoelement is brought about by the dividing wall.

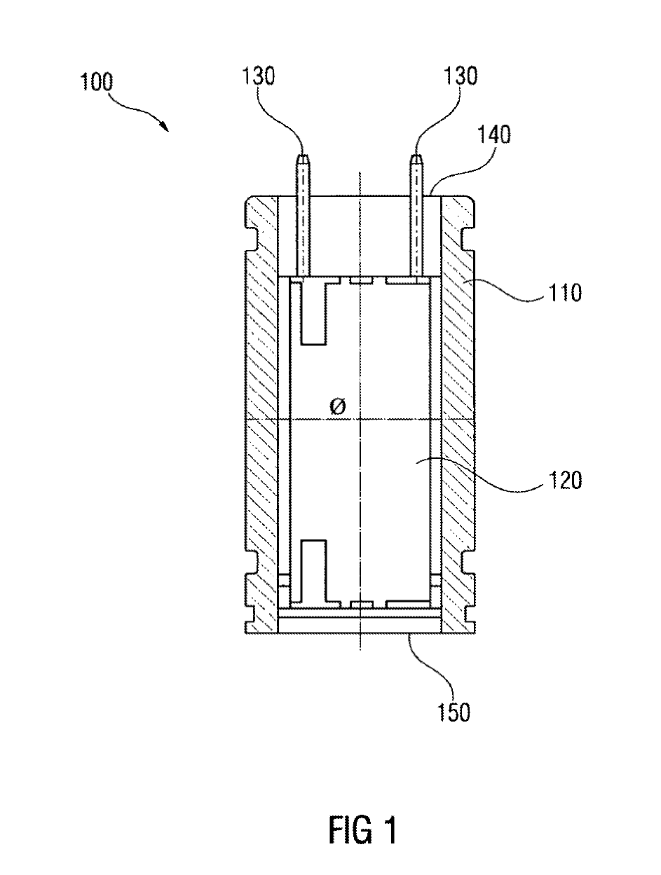

FIG. 1 shows a longitudinal section through a piezoelectric actuator 100 for a fuel injector. The piezoelectric actuator 100 comprises an essentially cylindrical housing 110, a piezoelement 120, electrical connections 130, a head plate 140 and a dividing wall 150. The housing 110 may be fabricated from steel and has on its outer side a plurality of circumferential grooves in order to facilitate axial locking of the housing 110, for example in a fuel injector.

The piezoelement 120 comprises a number of piezoceramic elements which are arranged in stack shape in the axial direction of the piezoelectric actuator 100. In another embodiment, the piezoceramic elements are arranged in a stack shape transversely with respect to the axial direction of the piezoelectric actuator 100. The piezoelement 120 bears at its upper end against the head plate 140 and at its lower end against the dividing wall 150. The head plate 140 may be composed of steel and can be embodied in one piece with the housing or connected to the housing 110, for example, by means of pressing in, screwing in, soldering, welding, caulking, flanging or some other way. The connection of the head plate 140 to the housing 110 may be embodied in such a way that a separate seal is not necessary to prevent an overflow of an aggressive medium such as, for example, oil, acid, spark ignition fuel or diesel fuel, to the piezoelement 120 in the region of the upper end of the piezoelectric actuator 100.

The electric connecting elements 130 lead in the axial direction through recesses in the head plate 140 and are electrically connected to the piezoelement 120. If the head plate 140 is composed of a conductive material, at least one of the electrical terminals 130 is made electrically insulated from the head plate 140. The electrical terminals 130 can be sealed in an electrically nonconductive fashion from the head plate 140 by means, for example, of a plastic or a ceramic, with the result that no aggressive medium can penetrate to the piezoelement 120 in this region either.

In a lower region of the piezoelectric actuator 100, the dividing wall 150 is connected to the housing 110. The dividing wall (diaphragm) 150 may be formed from steel, in particular from a spring-hardened steel, which has a high degree of resistance to corrosion, even in aggressive media. The dividing wall 150 is connected to the housing 110 so as to be sealed all around, for example by welding, in particular friction welding, or one of the other types of connection mentioned above with respect to the head plate 150.

In one embodiment, the piezoelectric actuator 100 is introduced into an injector body and may be welded thereto. In this context, an unfilled space can remain between the actuator 100 and the injector body. Instead of being connected to the housing 110, the dividing wall 150 is then connected to the injector body, e.g., by welding, in particular by friction welding.

In a further embodiment, the dividing wall 150 can have one or more breakthroughs, with the result that the dividing wall is mainly used for vertical suspension of the piezoelement 120 and less for sealing the piezoelement 120. In this case, protection of the piezoelement 120 against aggressive media can be provided by a separate sleeve or ceramic passivation. One of the breakthroughs can run in the form of a tear or in the form of a slit in a radial direction. The longitudinal axis of the actuator 100 can run through the breakthrough. A plurality of breakthroughs can be arranged with a symmetrical angle with respect to the longitudinal axis.

The piezoelement 120 is arranged in an axial direction between the head plate 140 and the dividing wall 150. If the piezoelement 120 is actuated by applying an electrical voltage to the electrical terminals 130, the piezoelement 120 changes its axial extent. The head plate 140 is sufficiently stiff not to be appreciably deformed. The dividing wall 150 is, on the other hand, of elastic design and deforms with the change in extent of the piezoelement 120. As a result of the deformation in the axial direction, a valve for controlling a flow of fuel is activated via the dividing wall 150.

Conventional piezoelectric actuators use for the generation of a prestress acting on the piezoelement 120 a hollow-cylindrical spring element which is arranged between the inner side of the housing 110 and the outer side of the piezoelement 120, concentrically with these two elements, and usually extends over the full length of the piezoelement 120. In order to bring about engagement of the elastic element on both sides of the piezoelement additional attachment elements or transmission elements are frequently necessary. In the case of the embodiment of the piezoelectric actuator 100 illustrated in FIG. 1, such elements can be dispensed with. As a result, the piezoelectric actuator 100 can be made more compact in the radial and/or axial direction(s) compared to the conventional actuator. Alternatively, the installation space which becomes free can be filled by an enlarged piezoelement 120, as a result of which increased efficiency and therefore a higher power density of the piezoelectric actuator 100 is achieved with the same external dimensions.

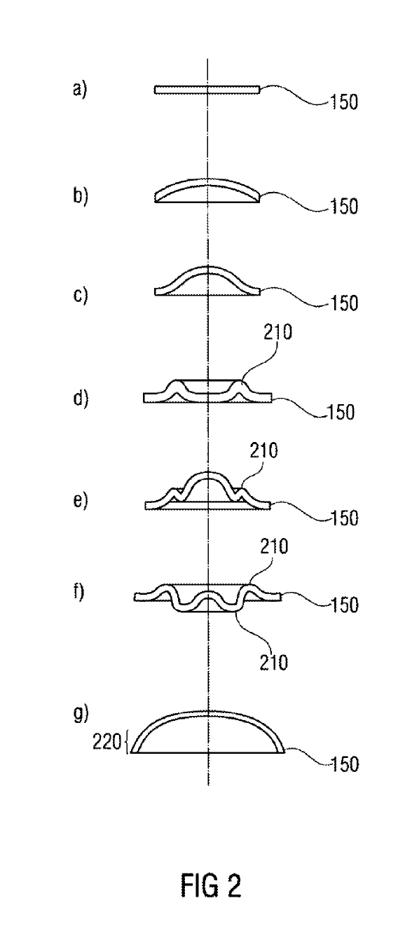

FIG. 2 shows longitudinal sections through various alternative embodiments of the dividing wall 150 of the piezoelectric actuator 100 from FIG. 1. All the illustrated dividing walls 150 are radially symmetrical with respect to the longitudinal axis of the piezoelectric actuator 100 from FIG. 1. In further embodiments (not illustrated), the dividing wall 150 can also have a non-circular outline. The outline of the dividing wall 150 can follow, in particular, a polygonal cross section of the housing 110 from FIG. 1. The beads and curved portions described below can also run in this case as illustrated or alternatively in certain sections parallel to the inner boundary of the housing 110. Spring properties of the dividing wall 150, in particular a spring characteristic curve, are varied by the embodiments shown. A thickness and a material of the dividing wall 150 also influences the spring properties. All the illustrated embodiments can be used as illustrated or conversely, with the result that a concave curved portion or bead becomes a convex curved portion or bead, and vice versa.

FIG. 2a shows the dividing wall 150 in a flat embodiment corresponding to the illustration in FIG. 1. The spring properties of the dividing wall 150 are mainly determined by the material of the dividing wall 150 and its thickness. The thickness of the dividing wall 150 is, for example, approximately 0.15 mm. A spring force which can be applied to the piezoelement 120 in FIG. 1 by the dividing wall is dependent on an actuation-conditioned vertical extent of the piezoelement 120 and can be in a range from approximately 50 N to approximately 1500 N, e.g., in a range between 100 N and 1000 N. However, other spring forces are also conceivable depending on the design of the piezoelement 120.

FIG. 2b shows an embodiment of the dividing wall 150 which is curved in the manner of a dome. The curvature in FIG. 2b is in the direction of the piezoelement 120, with the result that a relatively large prestress can act on the piezoelement 120.

FIG. 2c shows an embodiment of the dividing wall 150 which is curved similarly to that in FIG. 2b, wherein the dividing wall 150 is in the shape of a bell. As a result, improved stability of the dividing wall 150 in a region near to the axis is combined with good deformability in a region which is remote from the axis.

FIG. 2d shows the dividing wall 150 in an embodiment similar to that in FIG. 2a, but with a radially symmetrical, upwardly bulging bead 210. By means of the bead 210, it is possible to influence the stability of the dividing wall 150 over a predefined circumference, as a result of which the spring characteristic curve of the dividing wall 150 can be changed selectively.

FIG. 2e shows an embodiment of the dividing wall 150 which arises from combination of the embodiments in FIGS. 2b and 2d. The curved dividing wall 150 is provided with the bead 210. By virtue of this combination it is possible to influence further the deformability and the spring characteristic curve of the dividing wall 150. In a further embodiment, the curvature of the dividing wall 150 can also be based on the shape in FIG. 2c.

FIG. 2f shows an embodiment of the dividing wall 150 which is based on the embodiment in FIG. 2a, wherein two beads 210 with different radii and directions corresponding to the illustration in FIG. 2d are formed in the dividing wall 150. A bead 210 which is near to the axis runs downward and a bead 210 which is remote from the axis runs upward. By introducing a plurality of concentric beads 210 it is possible to increase the flexibility of the dividing wall 150 in the axial direction. This makes the spring characteristic curve of the dividing wall 150 flatter.

FIG. 2g shows a further embodiment of the dividing wall 150 on the basis of the embodiment illustrated in FIG. 2b. In contrast to the latter, in FIG. 2g an outer edge region of the dividing wall 150 merges with a conical collar 220 with an angle of aperture in a range of approximately 6-10°. A transition of the edge region of the dividing wall 150 into the collar 220 may have a bending radius which is greater than 1 mm, e.g., greater than 5 mm, with the result that no defined circumferential edge can be seen. The collar 220 can be connected in the axial or radial direction to the housing 110 of the actuator 100 from FIG. 1. The collar 220 can also be combined with any of the embodiments illustrated in FIGS. 2a to 2f. In this context, the junction between the outer region of the dividing wall 150 and the collar 220 can have the relatively large bending radius specified above.

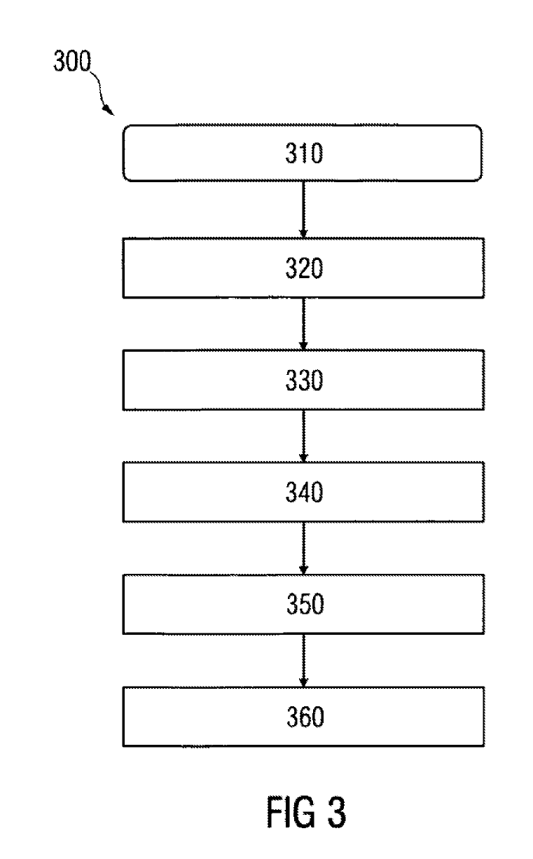

FIG. 3 shows a method 300 for manufacturing the piezoelectric actuator 100 from FIG. 1. The method 300 comprises the steps 310 to 360.

In step 310 the method 300 is in the starting state. In the following step 320, the piezoelement 120, the housing 110, the head plate 140 with the electrical terminals 130 and the dividing wall 150 are made available. In the subsequent step 330, the piezoelement 120 is inserted into the housing 110, wherein it remains movable in the axial direction for functional reasons, that is to say is not rigidly connected to the housing 110. Then, in step 340 the head plate 140 is connected to the housing 110, for example by welding or some other type of connection. This step can be dispensed with if the head plate 140 is formed in one piece with the housing 110. Then, in step 350 the dividing wall 150 is connected with axial prestressing to the housing 110. The desired prestress can be applied by an external clamp element, acting in the axial direction, until the dividing wall 150 is connected to the housing 110.

In other embodiments, the steps 330 to 350 can be varied in their sequence, for example in that in step 340 the head plate is connected to the housing 110 before the piezoelement is inserted in step 330. The method 300 is then in the final state 360.

By virtue of the simple design of the piezoelectric actuator 100 from FIG. 1 compared to a conventional actuator, the method 300 for manufacturing the piezoelectric actuator 100 is also simplified compared to a method for manufacturing a conventional actuator. The simplification is mainly based on the fact that steps for building separate spring elements for the piezoelement 120 and attachment elements for the spring elements are dispensed with. The steps 310 to 360 of the method 300 do not differ, or only differ slightly, from corresponding steps of a method for manufacturing a known piezoelectric actuator. The method 300 can therefore be carried out without large changes to existing production systems for piezoelectric actuators.

What is claimed is:

1. A piezoelectric actuator for a fuel injector, comprising:
a piezoelement configured to perform an axial activation; and
a dividing wall that protects the piezoelement from an overflow of a medium from the fuel injector;
wherein the dividing wall bears against an axial end of the piezoelement and extends transversely with respect to the direction of activation of the piezoelement, thereby prestressing the piezoelement in an axial direction.

2. The piezoelectric actuator of claim 1, wherein piezoelement is arranged in a housing between the dividing wall and a terminating element.

3. The piezoelectric actuator of claim 1, wherein the terminating element comprises electrical terminals for actuating the piezoelement.

4. The piezoelectric actuator of claim 1, wherein the dividing wall has a radially symmetrical shape.

5. The piezoelectric actuator of claim 1, wherein the dividing wall has a bead.

6. The piezoelectric actuator of claim 1, wherein the dividing wall is curved in the direction of the piezoelement.

7. The piezoelectric actuator of claim 1, wherein the dividing wall is formed from sheet steel.

8. A fuel injector, comprising:
a piezoelectric actuator, comprising:
a piezoelement configured to perform an axial activation; and
a dividing wall that protects the piezoelement from an overflow of a medium from the fuel injector;
wherein the dividing wall bears against an axial end of the piezoelement and extends transversely with respect to the direction of activation of the piezoelement, thereby prestressing the piezoelement in an axial direction.

9. The fuel injector of claim 8, wherein the piezoelement is arranged in a housing between the dividing wall and a terminating element.

10. The fuel injector of claim 8, wherein the terminating element comprises electrical terminals for actuating the piezoelement.

11. The fuel injector of claim 8, wherein the dividing wall has a radially symmetrical shape.

12. The fuel injector of claim 8, wherein the dividing wall has a bead.

13. The fuel injector of claim 8, wherein the dividing wall is curved in the direction of the piezoelement.

14. The fuel injector of claim 8, wherein the dividing wall is formed from sheet steel.
